(19) United States
(12) Patent Application Publication
(10) Pub. No.: US 2005/0289233 A1
(43) Pub. Date: Dec. 29, 2005

(54) Autonomic self-surveillance system and method for supported equipment

(75) Inventor: Omar Amin, Winchester (GB)

Correspondence Address: DILLION & YUDELL, LLP, 8911 N CAPITAL OF TEXAS HWY, SUITE 2110, AUSTIN, TX, 78759, US

(73) Assignee: International Business Machines Corporation, Armonk, NY (US)

(21) Appl. No.: 11/157,566

(22) Filed: Jun. 21, 2005

(30) Foreign Application Priority Data
Jun. 24, 2004 (GB) 0414174.3

(51) Int. Cl. G06F 15/173; G06F 1/16; H05K 5/00; H05K 7/00

(52) U.S. Cl. 709/224; 361/683

(57) ABSTRACT

A method and system is presented for autonomic self-surveillance of equipment. The system includes a coupler, which has a first component attached to a support rack and a second component attached to the equipment. When coupled, the coupler secures the equipment to the support rack. If the coupler becomes uncoupled, resulting in the equipment being uncoupled from the support rack, then an alert signal is sent over a network, thus notifying a remote location that the equipment is no longer secured to the support rack.

### PRIORITY CLAIM

This application claims priority of Great Britain Patent Application No. 0414174.3, filed on Jun. 24, 2004, and entitled, “Autonomic Self-Surveillance System and Method for Supported Equipment.”

### BACKGROUND OF THE INVENTION

1. Technical Field

The present invention relates in general to equipment such as computer servers mounted in supports such as racks. More specifically, the present invention relates to device for securing a computer server to a rack.

2. Description of the Related Art

Conventionally, server security in terms of tamper-proof hardware is done on the software level, typically utilizing SNMP (Simple Network Management Protocol). This is not effective for the times when a server (or other rack-mountable hardware) is physically taken out of a rack while the equipment is off. Current solutions amount to a lock on the server rack door. However this is more of a deterrent than a preventative measure, since if the lock is broken or left unfastened the server administrator is not notified. As used herein, the term rack is intended to cover any physically supporting hardware such as a rack or enclosure for supporting equipment such as a computer server.

High security facilities may have a video surveillance system installed on the server rooms, but again these do not offer an alert unless a person is watching the surveillance video in real time and this is quite an expensive solution.

A need therefore exists for autonomic self-surveillance for rack mounted equipment wherein the abovementioned disadvantage(s) may be alleviated.

### SUMMARY OF THE INVENTION

To address the limitations of the prior art, a method and system is presented for autonomic self-surveillance of equipment. The system includes a coupler, which has a first component attached to a support rack and a second component attached to the equipment. When coupled, the coupler secures the equipment to the support rack. If the coupler becomes uncoupled, resulting in the equipment being uncoupled from the support rack, then an alert signal is sent over a network, thus notifying a remote location that the equipment is no longer secured to the support rack.

The above, as well as additional purposes, features, and advantages of the present invention will become apparent in the following detailed written description.

### BRIEF DESCRIPTION OF THE DRAWINGS

The novel features believed characteristic of the invention are set forth in the appended claims. The invention itself, however, as well as a preferred mode of use, further objects and advantages thereof, will best be understood by reference to the following detailed descriptions of an illustrative embodiment when read in conjunction with the accompanying drawings, wherein:

FIG. 1 illustrates a perspective view of a rack-mounted server incorporating the present invention.

### DETAILED DESCRIPTION OF THE PREFERRED EMBODIMENT

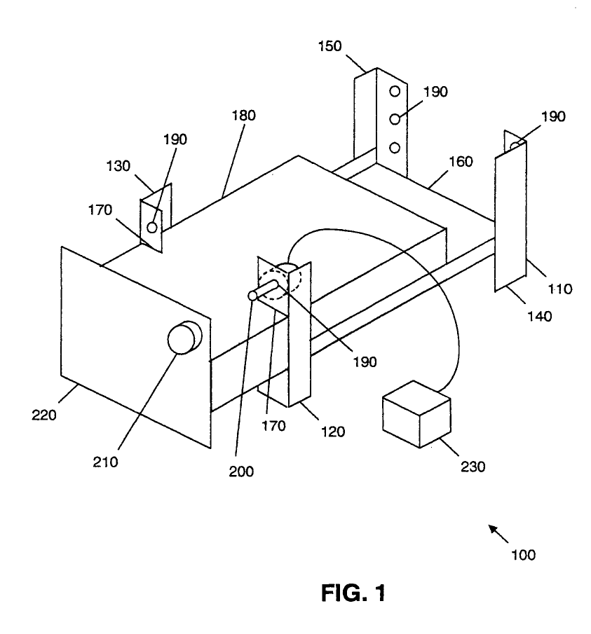

With reference now to the figures, and in particular to FIG. 1, there is depicted a rack-mount system 100 includes one or more racks 110 having vertical pillars 120, 130, 140 and 150 supporting therebetween shelves 160. The pillars 120 and 130 have openings 170 at the front of the rack to allow a server 180 to be inserted therebetween into the rack and supported on the shelf 160.

The pillars 120, 130, 140 and 150 have holes 190 therethrough, and a bolt 200 is provided behind one of the holes 190 above an opening 170 in the pillar 120. The bolt 200 is arranged to receive a screw 210 on a face plate 220 of the server 180. The bolt 200 is connected to an item of network hardware 230 and may be considered intelligent in the following sense: it detects when a screw 210 has been removed, and upon such detection it causes the network hardware 230 to generate an alert (for example, a SNMP trap or an email sent to a mobile phone).

It will be appreciated that the intelligent bolt 200 is not customized or adapted to any extent other than that it is conductive. In this way, when the screw 210 is removed from the bolt 200 a circuit is broken and this triggers an alert to be sent.

Thus, when the face plate 220 of the rack-mounted server 180 is unscrewed from the rack 110, an alert is immediately sent over the associated network (which may be, for example, wired or wireless) to the server administrator warning of possible tempering with the rack. It will be understood that the network hardware 230 is able to direct an alert signal to a particular receiver in the network, so avoiding a need for monitoring for a signal (such as an audible or visual signal).

It will be understood that the system described above can be applied equally to surveillance of other equipment such as computers mounted in other ways such as in enclosures.

It will be understood that the autonomic self-surveillance scheme described above may be viewed as applying enclosure management techniques to the domain of physical security. This enables the use of network-enabled hardware to generate an SNMP or other alert in response to an indication of the physical removal of a rack mounted computer system from an enclosure.

Thus, although physical security and surveillance is well-known in rack-mounted server systems, and although use of SNMP to manage enclosures (to configure and control equipment in the enclosures), is well-known, the system described above allows a server administrator to be informed almost immediately by different means when any of the administrator's rack mounted hardware is being moved or tampered with, a static alert being provided from the location of the removed device.

In conclusion it will be understood that system and method described above provides autonomic self-surveillance for rack-mounted servers affording the following advantages:
more responsive than simple locks and
a cheaper solution than real-time video surveillance.

1. A system for autonomic self-surveillance of equipment, the system comprising:
support means for supporting equipment to be surveilled;
securing means comprising first and second components for coupling together to secure the equipment to the support means; and
network alert means coupled to the securing means and arranged to produce an alert signal over an associated network in response to the first and second components becoming uncoupled.

2. The system of claim 1 wherein the equipment comprises a server.

3. The system of claim 1 wherein the support means comprises a rack.

4. The system of claim 1 wherein the first and second components are arranged to be coupled together by screwing.

5. The system of claim 4, wherein one of the first and second components comprises a conductive bolt.

6. The system of claim 1, wherein the alert signal comprises an SNMP signal.

7. The system of claim 1 wherein the alert signal comprises an email message.

8. A method for autonomic self-surveillance of equipment, the method comprising:
providing equipment to be surveilled;
providing support means supporting the equipment;
providing securing means comprising first and second components coupled together to secure the equipment to the support means; and
arranging to produce an alert signal coupled to the securing means and arranged to produce an alert signal over an associated network in response to the first and second components becoming uncoupled.

9. The method of claim 8, wherein the equipment comprises a server.

10. The method of claim 8, wherein the support means comprises a rack.

11. The method of claim 8, wherein the first and second components are arranged to be coupled together by screwing.

12. The method of claim 11, wherein one of the first and second components comprises a conductive bolt.

13. The method of claim 8 wherein the alert signal comprises an SNMP signal.

14. The method of claim 8 wherein the alert signal comprises an e-mail.

15. A system comprising:
a rack-mount system having multiple racks, each of the multiple racks having vertical pillars that support shelves between the multiple racks;
an opening in at least one of the vertical pillars to afford an insertion of a server onto one of the shelves;
a hole in at least one of the vertical pillars for receiving a bolt;
a network hardware connected to the bolt, the network hardware being capable of sending a warning signal over a network; and
a connector coupled to a face plate of the server, the connector being connectable with the bolt, wherein, in response to the connector becoming uncoupled from the bolt, the network hardware sends the warning signal over the network to a particular receiver on the network.

16. The system of claim 15, wherein the warning signal causes an audible signal at the particular receiver.

17. The system of claim 15, wherein the warning signal causes a visual signal at the particular receiver.
